(19) United States
(12) Patent Application Publication
(10) Pub. No.: US 2017/0115762 A1
(43) Pub. Date: Apr. 27, 2017

(54) ATTACHED STRUCTURE

(71) Applicant: TPK Touch Solutions (Xiamen) Inc., Xiamen (CN)

(72) Inventors: Jian-Bin Yan, Fujian (CN); Jian-Xing Luo, Fujian (CN); Yau-Chen Jiang, Hsinchu (TW)

(21) Appl. No.: 15/334,284

(22) Filed: Oct. 25, 2016

(30) Foreign Application Priority Data
Oct. 26, 2015 (CN) 201510700062.8

(51) Int. Cl. G06F 3/041; H05K 5/03; H05K 5/02; H05K 5/00

(52) U.S. Cl. CPC G06F 3/041; H05K 5/0017; H05K 5/03; H05K 5/0213; G06F 2203/04107

(57) ABSTRACT

An attached structure used in a touch display device is provided. The attached structure includes an attaching module, an attached module and an adhesive layer. The adhesive layer is disposed between the attaching module and the attached module to attach the attaching module and the attached module. A plurality of gas exhausting channels are formed on the adhesive layer such that a small amount of air is gathered in the gas exhausting channels in advance when the attaching module and the attached module are attached without being gathered between the attaching module or the attached module and the adhesive layer to affect the attaching result.

### RELATED APPLICATIONS

This application claims priority to China Application Serial Number 201510700062.8, filed Oct. 26, 2015, which is herein incorporated by reference.

### BACKGROUND

Technical Field

The present disclosure relates to an adhesive technology. More particularly, the present disclosure relates to an attached structure.

Description of Related Art

In electronic devices, different modules are adhered by using adhesive layers. For example, different layers of structures in a touch display panel are adhered by using adhesive layers. During the adhering process, a roller is used to press the layers to remove the air bubbles. However, no matter what method is used, only larger air bubbles are removed. The air can not be fully removed and a small amount of air is still distributed between the adhesive layer and the two adhered objects. During the transportation, assembling or usage of the touch display panel, the small amount of air may gather to the surfaces between the adhesive layer and the two adhered objects to form air bubbles to affect the adhering abilities of the adhesive layer.

Accordingly, what is needed is attached structure to address the above issues.

### SUMMARY

An aspect of the present disclosure is to provide an attached structure used in a touch display device is provided. The attached structure includes an attaching module, an attached module and an adhesive layer. The adhesive layer is disposed between the attaching module and the attached module to attach the attaching module and the attached module. A plurality of gas exhausting channels are formed on the adhesive layer such that a small amount of air is gathered in the gas exhausting channels in advance when the attaching module and the attached module are attached without being gathered between the attaching module or the attached module and the adhesive layer to affect the attaching result.

According to an embodiment of the present invention, each of the gas exhausting channels is a hole having a shape of a circle, a rectangle or a polygon.

According to an embodiment of the present invention, each of the gas exhausting channels is a trench of an elongated line shape or a curved shaped.

According to an embodiment of the present invention, the gas exhausting channels include a plurality of discontinuous trenches.

According to an embodiment of the present invention, the adhesive layer is a hollow rectangular structure formed in one piece and is formed around edges of the attaching module and the attached module.

According to an embodiment of the present invention, the adhesive layer includes two L-shaped structures.

According to an embodiment of the present invention, the two L-shaped structures are formed around edges of the attaching module and the attached module mirror-symmetrically to form a hollow rectangular shape.

According to an embodiment of the present invention, the adhesive layer substantially occupies the surface of each of the attaching module and the attached module.

According to an embodiment of the present invention, one of the attaching module and the attached module is a protective cover of a touch display device and the other one of the attaching module and the attached module is a display panel of the touch display device.

According to an embodiment of the present invention, the adhesive layer is disposed on an ink zone of the protective cover.

According to an embodiment of the present invention, the protective cover further includes a touch electrode structure formed between the protective cover and the adhesive layer.

According to an embodiment of the present invention, one of the attaching module and the attached module is a touch electrode substrate of a touch display device and the other one of the attaching module and the attached module is a protective cover of the touch display device.

According to an embodiment of the present invention, a first direction sensing electrode is formed on the touch electrode substrate and a second direction sensing electrode is formed on the protective cover.

According to an embodiment of the present invention, one of the attaching module and the attached module is a first direction touch sensing electrode substrate of a touch display device and the other one of the attaching module and the attached module is a second direction touch sensing electrode substrate of the touch display device.

According to an embodiment of the present invention, the adhesive layer is an optical adhesive, a pressure sensitive adhesive or a ultra-violet curing adhesive.

These and other features, aspects, and advantages of the present disclosure will become better understood with reference to the following description and appended claims.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a top view of an attached structured in an embodiment of the present invention;

FIG. 2 is a cross-sectional view of the attached structured along the line A-A′ in FIG. 1 in an embodiment of the present invention;

FIG. 3 is a top view of the adhesive layer formed on the attaching module in an embodiment of the present invention;

FIG. 4 is a top view of the adhesive layer formed on the attaching module in an embodiment of the present invention; and

FIG. 5 is a cross-sectional view of the attached structure in an embodiment of the present invention.

### DETAILED DESCRIPTION

In order to make the objects, technical solutions and advantages of the present disclosure apparent, diagrams in combination of examples are used to describe the present disclosure in further detail. It should be understood that the specific embodiments described herein are merely examples for explaining the present disclosure and are not intended to limit the present disclosure.

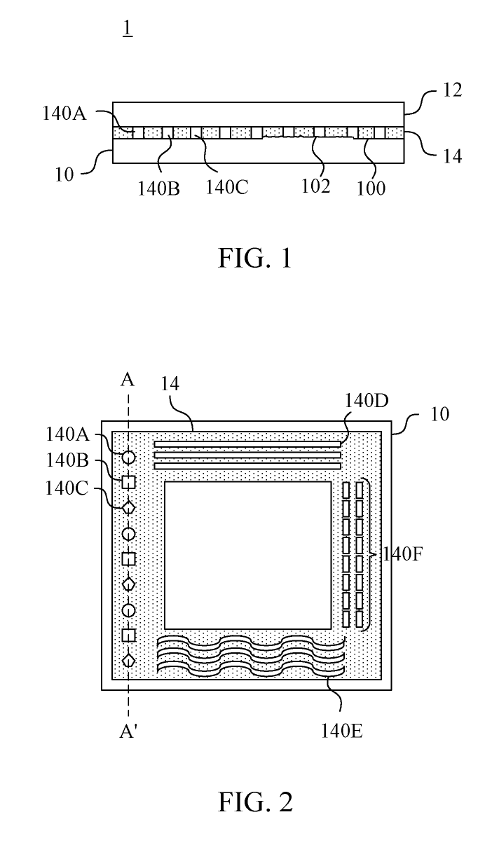

Reference is now made to FIG. 1 and FIG. 2 at the same time. FIG. 1 is a top view of an attached structured 1 in an embodiment of the present invention. FIG. 2 is a cross-sectional view of the attached structured 1 along the line A-A′ in FIG. 1 in an embodiment of the present invention. The attached structured 1 can be used in a touch display device (not illustrated).

As illustrated in FIG. 1, the attached structure 1 includes an attaching module 10, an attached module 12 and an adhesive layer 14. As illustrated in FIG. 2, the adhesive layer 14 is disposed between the attaching module 10 and the attached module 12 to attach the attaching module 10 and the attached module 12.

In order to give a clear illustration, the size of the attached module 12 is slightly smaller than the attaching module 10 in FIG. 1. However, the practical application is not limited thereto. In some embodiments, the attaching module 10 and the attached module 12 can be of the same size. In some embodiments, the size of the attaching module 10 can be larger than the size of the attached module 12. In some embodiments, the size of the attached module 12 can be larger than the size of the attaching module 10.

In the present embodiment, the adhesive layer 14 is illustrated as areas filled with dotted pattern in FIG. 1. The adhesive layer 14 attaches the attaching module 10 and the attached module 12 in the touch display device. In an embodiment, one of the attaching module 10 and the attached module 12 is a protective cover of a touch display device and the other one of the attaching module 10 and the attached module 12 is a display panel of the touch display device. In an embodiment, touch units (not illustrated) can be formed on the surface of the protective cover to realize a one-glass solution (OGS) touch panel.

In another embodiment, one of the attaching module 10 and the attached module 12 is a touch electrode substrate of the touch display device and the other one of the attaching module 10 and the attached module 12 is a protective cover of the touch display device. The touch electrode substrate can be a form having a single layer and two axises of touch electrodes. For example, a first direction sensing electrode and a second direction sensing electrode can be respectively formed on two sides of the touch electrode substrate. The protective cover can be made of transparent material such as a glass substrate or can be non-transparent material according to the requirements of the application.

In yet another embodiment, one of the attaching module 10 and the attached module 12 is a touch electrode substrate of the touch display device and the other one of the attaching module 10 and the attached module 12 is a protective cover of the touch display device. A first direction sensing electrode can be formed on the touch electrode substrate and a second direction sensing electrode can be formed on the protective cover. A structure that has two layers and two axises of electrodes is formed. In different embodiments, the protective cover can be made of transparent material such as a glass substrate or can be non-transparent material according to the requirements of the application.

In yet another embodiment, both of the attaching module 10 and the attached module 12 can be the touch electrode substrates in the touch display device, wherein one of the attaching module 10 and the attached module 12 is the first direction touch sensing electrode substrate of the touch display device and the other one of the attaching module 10 and the attached module 12 is the second direction touch sensing electrode substrate of the touch display device. A structure that has two layers and two axises of electrodes is formed.

In an embodiment, the adhesive layer 14 is an optically-clear adhesive (OCA). In different embodiments, the optically-clear adhesive can be a liquid form or a thin-film form. In another embodiment, the adhesive layer 14 is a pressure sensitive adhesive that generates the adhesive force when the attaching module 10 and the attached module 12 are pressed. In yet another embodiment, the adhesive layer 14 is a ultra-violet curing adhesive to generate the adhesive force when the adhesive layer 14 is exposed to the ultra-violet light.

In the present embodiment, the adhesive layer 14 is a hollow rectangular structure formed in one piece and is formed around edges of the attaching module 10 and the attached module 12. A plurality of gas exhausting channels 140A-140F are formed on the adhesive layer 14. In an example, suppose that the layer structure including the attaching module 10, the adhesive layer 14 and the attached module 12 forms a touch display device and one of the attaching module 10 and the attached module 12 is the protective cover of the touch display device, an ink area is formed on the protective cover to define a visible region and a non-visible region. Accordingly, the adhesive layer 14 having the hollow rectangular structure is disposed to an area corresponding to the non-visible region of the touch display device, which is the ink area of the protective cover. The gas exhausting channels 140A-140F of the adhesive layer 14 are covered by the ink area such that the visual effect is not affected thereby.

In different embodiments, the gas exhausting channels 140A-140F have different shapes. In the present embodiment, the gas exhausting channel 140A is a hole having a shape of a circle. The gas exhausting channel 140B is a hole having a shape of a rectangle. The gas exhausting channel 140C a hole having a shape of a pentagon. The gas exhausting channel 140D is a trench of an elongated line shape. The gas exhausting channel 140E is a trench of a curved shaped. The gas exhausting channel 140F includes a plurality of discontinuous trenches. In other embodiments, the holes or the trenches having different shapes can also be used to form the gas exhausting channels, which are not limited by the shapes mentioned above. Further, the number of the gas exhausting channels can be different depending on the practical requirements.

In an embodiment, when the attaching module 10 and the attached module 12 are attached by the adhesive layer 14, a conventional removing method is used to remove most of the air bubbles between the attaching module 10 and the attached module 12. During the subsequent procedures such as transportation, assembling or usage, the small amount of air existed between the adhesive layer 14 and attaching module 10 and the attached module 12 or inside the adhesive layer 14 would be easily gathered to the gas exhausting channels 140A-140F. The small amount of air will not be gathered to the spaces between the adhesive layer 14 and attaching module 10 or between the adhesive layer 14 and attached module 12 to form air bubbles to affect the adhering result therebetween.

Besides, the surface structure of the attaching module 10 and the attached module 12 may not be even. Further, despite the uneven condition of the original surface of the attaching module 10 and the attached module 12, the surface of the attaching module 10 and the attached module 12 may include the circuits or electrode structures formed by the etching process. The patterned and non-patterned areas result in differences of heights such that these areas are not smooth. Furthermore, when one of the attaching module 10 and the attached module 12 is a protective cover, an area of the surface around the edges, corresponding to such as the areas that contact the adhesive layer 14, may include printed ink layer to cover the neighboring circuits underneath. The larger granules of the ink layer also result in unevenness.

During the air bubbles removing process performed by the roller after the adhesive layer 14 attaches the attaching module 10 and the attached module 12, the unevenness of the surface structure described above makes it even harder to gather the small amount of air as air bubbles and exhaust the air by the rolling process. The adhering result of the adhesive layer 14 and the uneven surfaces is therefore affected. By using the attached structure 1 of the present invention, the gas exhausting channels 140A-140F are formed in the adhesive layer 14 to easily gather the small amount of air in the gas exhausting channels 140A-140F as air bubbles when the adhesive layer 14 attaches the attaching module 10 and the attached module 12. The air bubbles are thus easily to be exhausted during the rolling process such that the air does not affect the adhering result of the uneven surfaces. The tightness of the adhering result is enhanced.

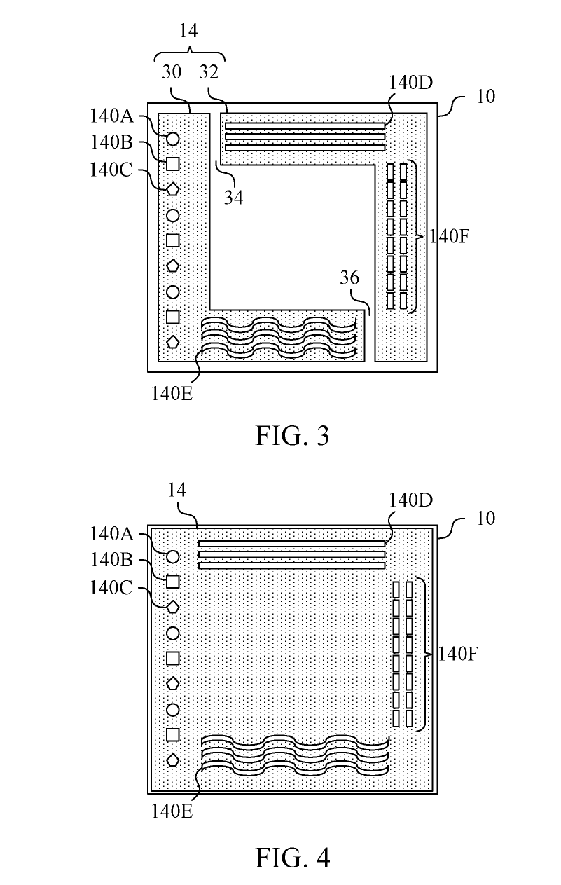

Reference is now made to FIG. 3. FIG. 3 is a top view of the adhesive layer 14 formed on the attaching module 10 in an embodiment of the present invention.

As illustrated in FIG. 3, the adhesive layer 14 in the present embodiment includes two independent L-shaped structures 30 and 32. The L-shaped structures 30 and 32 are formed around the edges of the attaching module 10 and the attached module 12 mirror-symmetrically to form a hollow rectangular shape. Two spaces 34 and 36 are included between the L-shaped structures 30 and 32. The adhesive layer 14 in the present embodiment may include the gas exhausting channels 140A-140F illustrated in FIG. 1 and may also include other types of gas exhausting channels.

In comparison to the hollow rectangular shape illustrated in FIG. 1, the spaces 34 and 36 of the L-shaped structures 30 and 32 provide additional gas exhausting paths. As a result, the gas exhausting channels 140A-140F and the spaces 34 and 36 provide the paths to gather the air to form the air bubbles such that the air bubbles can be exhausted when the adhesive layer 14 attaches the attaching module 10 and the attached module 12. The tightness of the adhering result is enhanced.

In an embodiments, besides the one piece structure or the two L-shaped structures, the hollow rectangular shape described above can be formed by more than two independent structures, wherein each two of the independent structures include a space therebetween to provide more paths for gathering the air to form air bubbles such that the air bubbles can be exhausted to provide a better adhering result.

Reference is now made to FIG. 4. FIG. 4 is a top view of the adhesive layer 14 formed on the attaching module 10 in an embodiment of the present invention.

As illustrated in FIG. 4, the adhesive layer 14 in the present embodiment substantially occupies the surface of the attaching module 10. More specifically, the area that the adhesive layer 14 in the present embodiment is disposed is different from the hollow rectangular shape in the previous embodiment. The adhesive layer 14 in the present embodiment occupies the whole area (e.g. a rectangular shape of area) of the surface of the attaching module 10. As a result, when the attached module 12 is attached to the attaching module 10 through the adhesive layer 14, the adhesive layer 14 substantially occupies the surface of the attaching module 10 and the attached module 12. It is appreciated that the term “substantially” means that according to the practical manufacturing process, the adhesive layer 14 may not be completely aligned to the edges of the attaching module 10 and the attached module 12. A space, such as but not limited to 10% of the area of the surface, may be left without being occupied by the adhesive layer 14. In other words, the size of the adhesive layer 14 in the present embodiment may be slightly smaller than the size of the attaching module 10 and the attached module 12. After the adhesive layer 14 in the present embodiment is disposed, the gas exhausting channels 140A-140F illustrated in FIG. 1 or other types of gas exhausting channels can be formed.

When touch electrode structures are formed on the attaching module 10 and the attached module 12, the adhesive layer 14 provides both the adhering and the protection mechanisms since the adhesive layer in the present embodiment occupies the surface of the side of the attaching module 10 and the attached module 12 that includes the touch electrode structures. In an example, suppose that one of the attaching module 10 and the attached module 12 is the protective cover having the touch electrode structures of the touch display device, the adhesive layer 14 in the present embodiment is substantially disposed to occupy the surface of the side of the protective cover that include the touch electrode structures. As a result, the touch electrode structures are formed between the protective cover and the adhesive layer and are protected thereby.

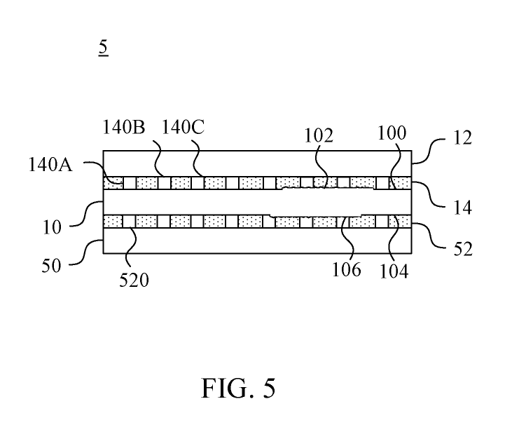

Reference is now made to FIG. 5. FIG. 5 is a cross-sectional view of the attached structure 5 in an embodiment of the present invention. In the present embodiment, besides the layer structure shown in FIG. 2 that includes the attaching module 10, the attached module 12 and the adhesive layer 14, the attached structure 5 further includes another attached module 50 and another adhesive layer 52.

The adhesive layer 52 attaches the attaching module 10 and the attached module 50. A plurality of gas exhausting channels 520 are formed on the adhesive layer 52 to provides the paths for gathering the air to form the air bubbles and making the air bubbles exhausted. When the adhesive layer 52 attaches the attaching module 10 and the attached module 50, the gas exhausting channels 520 is beneficial to exhaust the air bubbles.

In an embodiment, the attached module 12 is a one-glass solution touch panel with cover mechanisms, and the attaching module 10 is a display panel. In an embodiment, the attached module 12 is a protective cover, the attaching module 10 is a touch electrode substrate and the attached module 50 is a display panel. In another embodiment, the attached module 12 is a protective cover, the attaching module 10 is a first direction touch sensing electrode substrate and the attached module 50 is a second direction touch sensing electrode substrate.

In an embodiment, when the layer structure that includes the attaching module 10, the attached module 12 and the attached module 50 forms such as a touch display device and includes a corresponding visible region and a non-visible region, the positions of the gas exhausting channels 140A-140C of the adhesive layer 14 and the gas exhausting channels 520 of the adhesive layer 52 can be disposed in the non-visible region. The uneven brightness of the display result of the touch display device generated due to the uneven distribution of the gas exhausting channels can be avoided. For example, when the attached module 50 is the display panel, the gas exhausting channels 140A-140C of the adhesive layer 14 and the gas exhausting channels 520 of the adhesive layer 52 can be disposed in the non-visible region of the attached module 50 to obtain a better display result.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. An attached structure comprising:
an attaching module;
an attached module; and
an adhesive layer disposed between the attaching module and the attached module to attach the attaching module and the attached module, wherein a plurality of gas exhausting channels are formed on the adhesive layer such that a small amount of air is gathered in the gas exhausting channels in advance when the attaching module and the attached module are attached without being gathered between the attaching module or the attached module and the adhesive layer to affect the attaching result.

2. The attached structure of claim 1, wherein each of the gas exhausting channels is a hole having a shape of a circle, a rectangle or a polygon.

3. The attached structure of claim 1, wherein each of the gas exhausting channels is a trench of an elongated line shape or a curved shaped.

4. The attached structure of claim 1, wherein the gas exhausting channels comprise a plurality of discontinuous trenches.

5. The attached structure of claim 1, wherein the adhesive layer is a hollow rectangular structure formed in one piece and is formed around edges of the attaching module and the attached module.

6. The attached structure of claim 1, wherein the adhesive layer comprises two L-shaped structures.

7. The attached structure of claim 6, wherein the two L-shaped structures are formed around edges of the attaching module and the attached module mirror-symmetrically to form a hollow rectangular shape.

8. The attached structure of claim 1, wherein the adhesive layer substantially occupies the surface of each of the attaching module and the attached module.

9. The attached structure of claim 1, wherein one of the attaching module and the attached module is a protective cover of a touch display device and the other one of the attaching module and the attached module is a display panel of the touch display device.

10. The attached structure of claim 9, wherein the adhesive layer is disposed on an ink zone of the protective cover.

11. The attached structure of claim 9, wherein the protective cover further comprises a touch electrode structure formed between the protective cover and the adhesive layer.

12. The attached structure of claim 1, wherein one of the attaching module and the attached module is a touch electrode substrate of a touch display device and the other one of the attaching module and the attached module is a protective cover of the touch display device.

13. The attached structure of claim 12, wherein a first direction sensing electrode is formed on the touch electrode substrate and a second direction sensing electrode is formed on the protective cover.

14. The attached structure of claim 1, wherein one of the attaching module and the attached module is a first direction touch sensing electrode substrate of a touch display device and the other one of the attaching module and the attached module is a second direction touch sensing electrode substrate of the touch display device.

15. The attached structure of claim 1, wherein the adhesive layer is an optical adhesive, a pressure sensitive adhesive or a ultra-violet curing adhesive.
